(19) United States
(12) Patent Application Publication
(10) Pub. No.: US 2008/0128839 A1
(43) Pub. Date: Jun. 5, 2008

(54) Electronic Apparatus Applied Anodic Bonding

(76) Inventors: Hideo Sotokawa, Yokohama (JP); Hiroaki Huruichi, Yokohama (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/573,371

(22) PCT Filed: Aug. 30, 2005
(86) PCT No.: PCT/JP05/15740

§ 371 Date: Aug. 9, 2007

(30) Foreign Application Priority Data
Sep. 30, 2004 (JP) 2004-285634

(51) Int. Cl. H01L 29/84

(52) U.S. Cl. 257/415; 257/E29.324

(57) ABSTRACT

An electronic apparatus suppressing damages to a device not having high durability to a high voltage of a structure including a first member having a first electrode and a device, and a second member having a second electrode in which the first electrode and the second electrode, are formed in a region not overlapping the device, the first member and the second member are anodically bonded by the application of a voltage between the first electrode and the second electrode and the device is encapsulated between the first member and the second member.

### CLAIM OF PRIORITY

The present application claims priority from Japanese Patent Application No. JP 2004-285634 filed on Sep. 30, 2004, the entire contents of which are hereby incorporated by reference into this application.

### FIELD OF THE INVENTION

The present invention concerns an electronic apparatus packaged by encapsulating a device with anodic bonding.

### BACKGROUND OF THE INVENTION

Since a semiconductor such as Si and glass can be bonded directly in anodic bonding, this has been utilized in the field of MEMS (Micro Electro mechanical Systems) in which micro mechanical parts are manufactured by fabricating mainly Si.

Typical examples of actually applying the anodic bonding include various sensor parts such as pressure sensors, acceleration sensors, and angular velocity sensors, or micro pumps typical represented by ink jet nozzles of ink jet printers.

They are manufactured by at first fabricating Si with anisotropic etching and then anodically bonding the same to a separate glass layer to obtain an encapsulated structure. The anodic bonding technique has been used for such products since anodic bonding directly bonds Si and glass and can detect an external pressure change or the like extremely sensitively.

In recent years, all devices including MEMS devices and various kinds of sensors have been improved in the function and made complicate such as by incorporation of integrated circuits, and those devices having low durability to the high voltage have been increased.

In a case of bonding by appending a substrate such as of glass to the upper surface of a device by anodic bonding, it usually requires a voltage as high as of about several hundred volts.

However, in a case where a device can not withstand such a high voltage, since the device is electrostatically destroyed by the high voltage, the anodic bonding method can not be applied.

An example capable of bonding even at a relatively low voltage is disclosed, for example, in Japanese Laid-Open No. 2002-348149.

### SUMMARY OF THE INVENTION

Also in Japanese Laid-Open No. 2002-348149 described above, since an electrode to which a voltage is applied for conducting anodic bonding substantially covers the entire surface of a device, while local bonding can be attached at a thin portion of a substrate, a high voltage at about 200 V is after all applied to the device.

That is, in a case of application to a device with a low durability to a high voltage, the existent anodic bonding technique may possibly deteriorated the inherent function of the device.

The present invention intends to provide an anodically bonded encapsulated type electronic apparatus capable of ensuring high reliability even in a device having low durability to a high voltage.

For addressing the problems described above, the present invention provides an electronic apparatus having a first member including a first electrode and a device electrically insulated from the first electrode, and a second member having a second electrode, in which the first member and the second member are anodically bonded by the application of a voltage between the first electrode and the second electrode, and the device is thereby encapsulated and the first electrode and the second electrode are formed in a region not overlapping the device.

### BRIEF DESCRIPTION OF THE DRAWINGS

FIG. 1 is a cross sectional view of an electronic apparatus as an example of the invention;

FIG. 2 is a cross sectional view of an electronic apparatus another example of the invention;

FIG. 3 is a cross sectional view of an electronic apparatus as other example of the invention;

FIG. 4 is a cross sectional view of an electronic apparatus as other example of the invention;

FIG. 5 is a cross sectional view of an electronic apparatus as other example of the invention;

FIG. 6 is a cross sectional view of an electronic apparatus as other example of the invention;

FIG. 7 is a cross sectional view of an electronic apparatus as other example of the invention; and

FIG. 8 is a cross sectional view of an electronic apparatus as other example of the invention.

### DETAILED DESCRIPTION OF THE PREFERRED EMBODIMENTS

The invention can provide an electronic apparatus having an anodically bonded structure with no deterioration of the reliability of a device not having high durability to a high voltage.

A plurality of embodiments for practicing the invention are to be described.

### Example 1

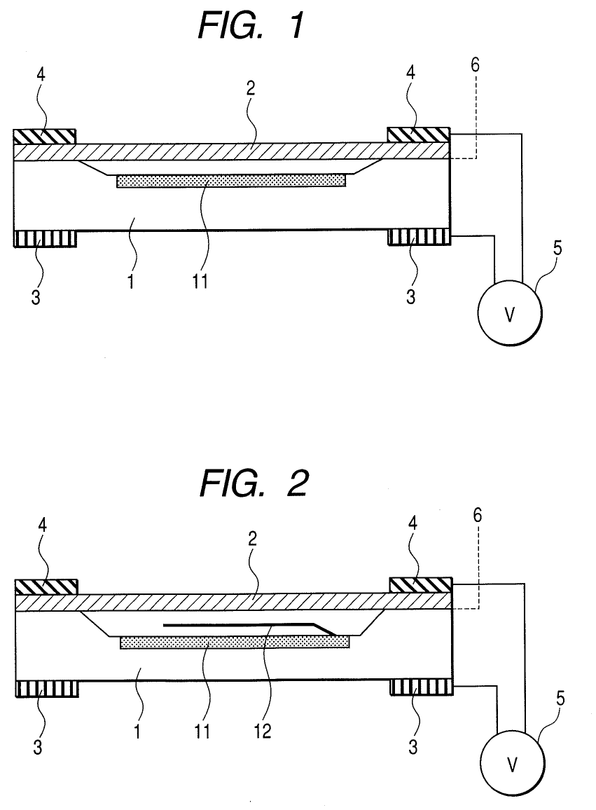

FIG. 1 is a cross-sectional view of an electronic apparatus as an example of the present invention, which shows a state that an anodic bonding is performed.

The electronic apparatus has a structure in which a substrate 1 and a substrate 2 are bonded.

The substrate 1 has a cavity at a surface opposed to the substrate 2 and having a device 11 including a thin film electronic circuit or the like not having a high durability to a high voltage at the bottom of the cavity, and has an electrode 3 for voltage application upon anodic bonding at the periphery of the device 11 on the surface opposed to the substrate 2, that is, at a position dodging and not overlapping the device 11.

The substrate 2 has an electrode 4 for voltage application upon anodic bonding at the position corresponding to the electrode 3 on the rear face opposing to the substrate 1.

By the application of a voltage between the electrode 3 and the electrode 4, the substrate 1 and the substrate 2 are bonded by anodic bonding.

This structure is formed as described below.

At first, the electrode 3 and the electrode 4 are formed at the positions opposed to each other respectively to the substrate 1 formed with the device 11 and the substrate 2. The electrodes 3 and 4 are formed by way of photolithography or metal mask by sputtering, vapor deposition under heating or CVD (Chemical Vapor Deposition).

Then, they are bonded with the electrode 3 and the electrode 4 being opposed to each other.

Then, heating is conducted while applying a voltage to the electrode 3 and the electrode 4 by a voltage application power source 5 to conduct anodic bonding.

This can conduct clean and highly reliable encapsulation at the position 6 without damaging the device 11.

In this example, Si was used for the substrate 1, float glass was used for the substrate 2, and Al was used for the electrode 3 and the electrode 4. However, they are not restrictive and the substrate 2, for example, may be formed of a dielectric material such as glass containing elements such as Na capable of migration upon voltage application.

For the electrode 3 and the electrode 4, a metal including at least one member selected from Al, Cr, Ti, V, Mo, W, Cu, Ag, Ni, Pt, Pd, Pb, and Sn can be used.

Au may also be incorporated with no trouble at all with an aim of lowering the contact resistance or DC current resistance to the surface or the inner layer of the electrode 3 and the electrode 4.

The application voltage can be properly changed depending on the situations within a range from several volts to several hundred volts. Also the heating temperature can be changed properly depending on the situation within a range from several ° C. to several hundreds ° C.

### Example 2

FIG. 2 shows a cross-sectional view of an electronic apparatus as another example of the invention showing the state of conducting anodic bonding.

Example 2 is different from Example 1 in that a substrate in which a device 11 including a thin film electronic circuit or the like not having a high durability to a high voltage and an MEMS (Micro Electro Mechanical System) 12 are formed is used as the substrate.

The electrode 3 and the electrode 4 are formed at the periphery of the MEMS while dodging and not overlapping the MEMS to conduct anodic bonding.

### Example 3

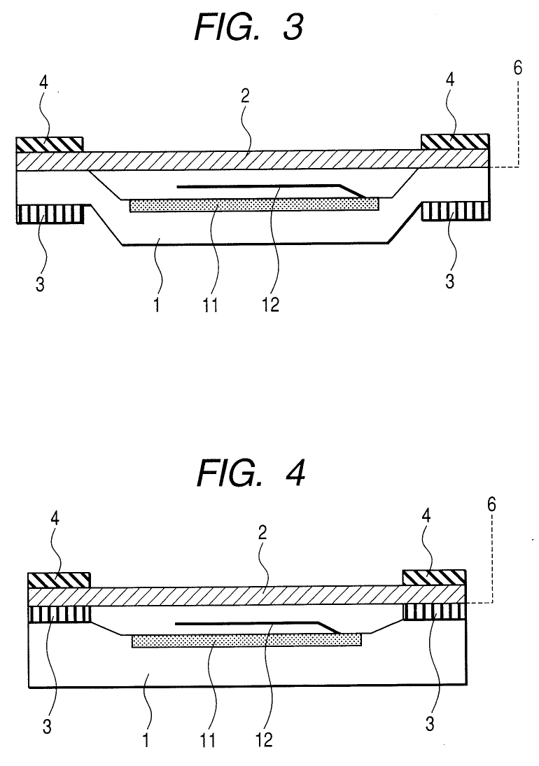

FIG. 3 shows a cross-sectional view of an electronic apparatus as another example of the invention showing the state of conducting anodic bonding.

Example 3 is different from Example 2 in that the thickness of the substrate is reduced at the periphery of a cavity (concave portion) of Example 2. The rear face of the tapered portion of the cavity is also tapered.

Since the structure can lower the voltage upon anodic bonding, load applied on the device can be decreased.

### Example 4

FIG. 4 shows a cross-sectional view of an electronic apparatus as other example of the invention.

Example 4 is different from Example 2 in that arrangement of the electrode 3 is changed to the opposing surface between the substrate 1 and the substrate 2. Accordingly, the electrode 3 constitute a bonded interface.

Anodic bonding can be conducted by applying a voltage to the electrode 3 and the electrode 4. Since detailed procedures for conducting anodic bonding are similar with those in Examples 1 to 3, they are not described.

It has an advantage other than that described for Example 2 in that the applied voltage can be lowered since the thickness along which the voltage is applied is only for the portion of the substrate 2.

### Example 5

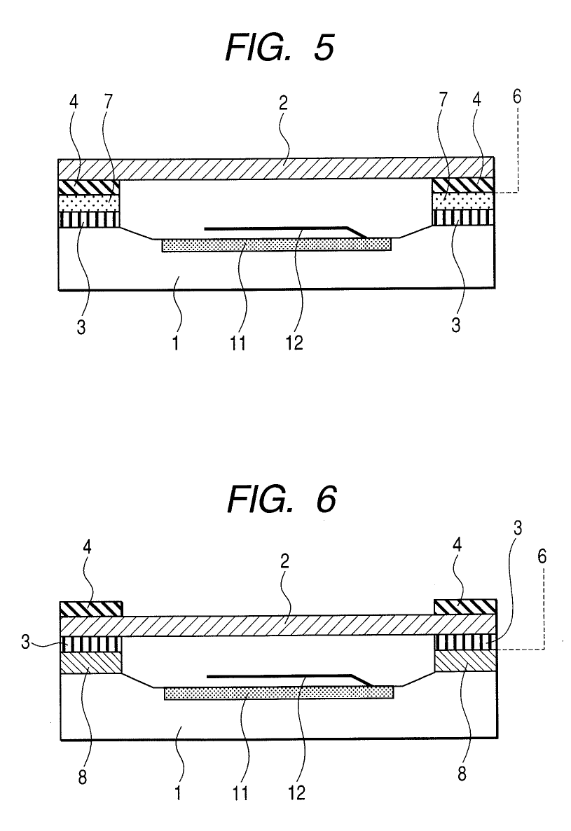

FIG. 5 shows a cross-sectional view of an electronic apparatus as other example of the invention.

Example 5 is different from Example 4 in that arrangement of the electrode 4 is changed to the opposing surface between the substrate 1 and the substrate 2 and, further, a glass dielectric member 7 is disposed between the electrode 3 and the electrode 4.

While the dielectric body 7 can also be formed with a thin film technique such as CVD, it is not restricted thereto. Since detailed procedures for conducting anodic bonding are similar with those in Examples 1 to 4, they are not illustrated described here.

Other advantage than that described for Example 4 resides in that since the thickness along which the voltage is applied is only for the portion of the dielectric body 7, the thickness can be decreased extremely and, accordingly, the applied voltage can also be lowered extremely.

### Example 6

FIG. 6 shows a cross-sectional view of an electronic apparatus as other example of the invention.

Example 6 is different from Example 4 in that a soft metal 8 is disposed below the electrode 3.

Since detailed procedures for conducting the anodic bonding are similar with those in Examples 1 to 3, they are not described herein.

Other advantage than that described in Example 4 resides in that thermal stresses generated by heating upon anodic bonding in a case where the heat expansion coefficient is different between the substrate 1 and the substrate 2 can be moderated by the soft metal 8.

### Example 7

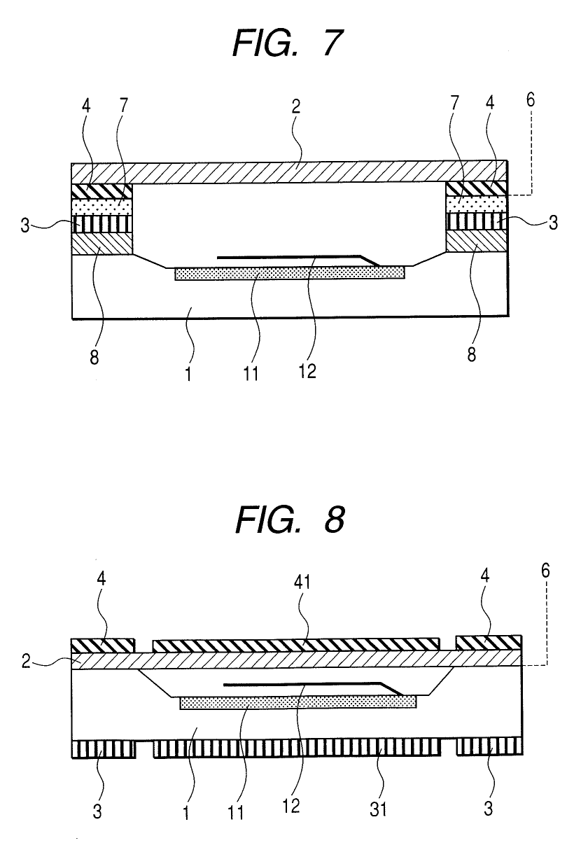

FIG. 7 shows a cross-sectional view of an electronic apparatus as other example of the invention.

Example 7 is different from Example 5 in that the soft metal 8 is disposed below the electrode 3.

Since detailed procedures for conducting the anodic bonding are similar with those in Examples 1 to 3, they are not described herein.

Other advantage than that described in Example 5 resides in that thermal stresses generated by heating upon anodic bonding in a case where the heat expansion coefficient is different between the substrate 1 and the substrate 2 can be moderated by the soft metal 8.

### Example 8

FIG. 8 shows a cross-sectional view of an electronic apparatus as other example of the invention.

Example 8 is different from Example 1 in that an electrode 31 and an electrode 41 for electromagnetic shielding are disposed on the side of the electrode 3 and the electrode 4 respectively.

Since detailed procedures for conducting anodic bonding are similar with those in Examples 1 to 3, they are not described herein.

Other advantage than that described in Example 1 resides in that by the provision of the electrode 31 and electrode 41 for electromagnetic shielding, a countermeasure (electromagnetic shielding countermeasure) for EMI (Electro magnetic Interference) for the device 11 and the device 12 can be taken.

A significant difference from the related art resides in that electrical insulation is attained between the electrode 3 and the electrode 31 and between the electrode 4 and the electrode 41.

In view of the foregoing eight examples, the followings can be seen.

At first, even in a case where a device portion not having a high durability to a high voltage is present, damages to the device due to voltage can be avoided essentially by arranging the electrode for anodic bonding in a region at the periphery of the device portion to a position while dodging and not overlapping the device portion. Accordingly, the device can be encapsulated reliably by the anodic bonding also to a device having not high durability to the high voltage.

Further, by forming the electrode for anodic bonding to a reduced thickness on the inner side where two substrates to be bonded are opposed to each other while putting therebetween a dielectric body such as of an Na element that migrates by the voltage and contributes to the anodic bonding, anodic bonding can be conducted at a voltage of several to several tens volts not requiring application of a voltage as high as several hundreds volts conducted so far in the existent anodic bonding.

Further, by providing a soft metal below the electrode or the like in a region conducting the anodic bonding described above, the thermal stresses caused by heating upon anodic bonding can be moderated in a case where the thermal expansion coefficient is different between the substrate 1 and the substrate 2 to be bonded anodically thereby capable of preventing destruction of the anodic bonding portion.

Further, with the constitution of conducting anodic bonding by forming an electrode for anodic bonding to a decreased thickness on the inner side where two substrates to be bonded an opposed to each other while sandwiching therebetween a dielectric body such as an Na element that moves under voltage and contributes to the anodic bonding, it is no more necessary that at least one of the two substrates which were necessary in the existent anodic bonding is no more necessary a dielectric body such as glass and, accordingly, a metal can be used as an upper substrate for example conducting encapsulation. This can take EMI countermeasure for the device.

Further, even in a case where the two substrates for conducting anodic bonding are made of dielectric body, EMI countermeasure for the device can be taken by arranging the metal so as to cover the portions above and below the device in addition to the metal that functions as the electrode for anodic bonding.

An arrangement of respective electrodes in a pair of substrate according to the present invention ensures that a device formed in one of the pair of substrates is sealed without deterioration thereof between the pair of substrates joined by anodic bonding using the respective electrodes, while voltage tolerance of the device is not high. Therefore, an electronic apparatus e.g. of a CSP (Chip Size Package) type having the device thus sealed by the anodic bonding method is realized as well as securing its high reliability.

What is claimed is:

1. An electronic apparatus comprising:
a first member having a first electrode and a device; and
a second member having a second electrode,
wherein the first electrode and the second electrode are formed in a region not overlapping the device,
the first member and the second member are anodically bonded by the application of a voltage between the first electrode and the second electrode, and
the device is encapsulated between the first member and the second member.

2. The electronic apparatus according to claim 1,
wherein the first electrode or the second electrode includes at least one metal selected from Al, Cr, Ti, V, Mo, W, Cu, Ag, Ni, Pt, Pd, Pb, and Sn.

3. The electronic apparatus according to claim 1,
wherein a dielectric body containing an element that moves by the application of a voltage is interposed between the first electrode and the second electrode in a case where the first electrode and the second electrode are formed to the surfaces of the substrates opposed to each other respectively.

4. The electronic apparatus according to claim 1,
wherein at least one soft metal selected from Al, Cu, Ag, Ni, Pt, Pd, Pb, Sn, and Au is interposed to a bonded interface between the first electrode and the second electrode.

5. The electronic apparatus according to claim 3,
wherein the dielectric body has a pattern substantially identical with the first electrode or the second electrode.

6. An electronic apparatus comprising:
a first member having a first electrode and a device formed in a region surrounded with the first electrode; and
a second member having a second electrode,
wherein the first member and the second member are anodically bonded by the application of a voltage between the first electrode and the second electrode, and
the devices is encapsulated between the first member and the second member.

7. The electronic apparatus according to claim 6,
wherein the first electrode or the second electrode includes at least one metal selected from Al, Cr, Ti, V, Mo, W, Cu, Ag, Ni, Pt, Pd, Pb, and Sn.

8. The electronic apparatus according to claim 6,
wherein a dielectric body containing an element that moves by the application of a voltage is interposed between the first electrode and the second electrode in a case where the first electrode and the second electrode are formed to the surfaces of the substrates opposed to each other respectively.

9. The electronic apparatus according to claim 6,
wherein at least one soft metal selected from Al, Cu, Ag, Ni, Pt, Pd, Pb, Sn, and Au is interposed to the bonded interface between the first electrode and the second electrode.

10. An electronic apparatus according to claim 8,
wherein the dielectric body has a pattern substantially identical with the first electrode or the second electrode.
